(19) United States
(12) Patent Application Publication
(10) Pub. No.: US 2010/0140699 A1
(43) Pub. Date: Jun. 10, 2010

(54) SEMICONDUCTOR DEVICE AND METHOD FOR MANUFACTURING THE SAME

(76) Inventor: Kwang-Young Ko, Bucheon-si (KR)

Correspondence Address: SHERR & VAUGHN, PLLC, 620 HERNDON PARKWAY, SUITE 320, HERNDON, VA, 20170, US

(21) Appl. No.: 12/630,267

(22) Filed: Dec. 3, 2009

(30) Foreign Application Priority Data
Dec. 4, 2008 (KR) 10-2008-0122791

(51) Int. Cl. H01L 29/78; H01L 21/336

(52) U.S. Cl. 257/337; 438/286; 257/E29.261; 257/E21.417

(57) ABSTRACT

A semiconductor device includes a logic device and a LDMOS device. The logic device including a first well of a first conductive type formed in the substrate, a first source region and a first drain region formed in the first well, and a first gate electrode formed over the first well. The LDMOS device including a deep well of the first conductive type formed in a second substrate, a body region of a second conductive type and a second well of a first conductive type formed in the deep well, a second source region formed in the body region, a second drain region formed in the second well, a second gate electrode formed over the second substrate, and an impurity layer of the first conductive type formed in the second substrate under the second gate electrode.

The present application claims priority under 35 U.S.C. §119 to Korean Patent Application No. 10-2008-0122791 (filed on Dec. 4, 2008), which is incorporated herein by reference in its entirety.

### BACKGROUND

Generally, a power MOS electric field transistor (MOSFET) has an input impedance that is higher than a bipolar transistor. A power MOSFET also has advantages in exhibiting large power gains and a simple gate driving circuit. Further, since the power MOSFET is a unipolar device, it has an advantage in that there is no time delay caused due to accumulation or recombination due to a minority carrier during the turn-off of the power MOSFET, and the like. Therefore, the use of a power MOSFET for a switching mode power supplying apparatus, lamp stabilization, and a motor driving circuit is gradually increasing.

As a power MOSFET, a double diffused MOSFET structure using a planar diffusion technology has been widely used. A representative power MOSFET is an LDMOS transistor.

### SUMMARY

Embodiments relate to a semiconductor device and a method for manufacturing the same which reduces on resistance in an LDMOS device.

In accordance with embodiments, a semiconductor device can include at least one of the following: a substrate; a first conductive type well formed in the substrate; and an LDMOS device formed on and/or over the substrate, the LDMOS device including a gate electrode, a source region formed in the substrate at one side of the gate electrode, a drain region formed in the substrate at the other side of the gate electrode, and a first conductive type impurity layer formed on and/or over the substrate at a lower side of the gate electrode.

In accordance with embodiments, a semiconductor device can include at least one of the following: a first conductive type well formed in a first substrate; a source region and a drain region formed in the first conductive type well; and a gate electrode formed on and/or over the first substrate; and a first conductive type deep well formed in a second substrate; a second conductive body and a first conductive well formed in the first conductive type deep well; a source region formed in the second conductive body; a drain region formed in the first conductive well; and a gate electrode formed on the second substrate, the second substrate at the lower side of the gate electrode of the LDMOS device being formed with the first conductive type impurity layer.

In accordance with embodiments, a semiconductor device can include at least one of the following: a first substrate; a second substrate; a logic device including a first well of a first conductive type formed in the substrate, a first source region and a first drain region formed in the first well, and a first gate electrode formed over the first well; and a LDMOS device including a deep well of the first conductive type formed in a second substrate, a body region of a second conductive type and a second well of a first conductive type formed in the deep well, a second source region formed in the body region, a second drain region formed in the second well, a second gate electrode formed over the second substrate, and an impurity layer of the first conductive type formed in the second substrate under the second gate electrode.

In accordance with embodiments, a method for manufacturing a semiconductor device may include at least one of the following: forming a first conductive type deep well in a second conductive type substrate; forming a second conductive type body in the first conductive type deep well; forming a first conductive type impurity layer and a first conductive well for forming a drain region at one side of the second conductive type body; forming a gate electrode on and/or over the substrate corresponding to the region in which the first conductive type impurity layer is formed; and then forming a source region in the second conductive type body and a drain region in the first conductive type well.

In accordance with embodiments, a method for manufacturing a semiconductor device may include at least one of the following: forming a deep well of a first conductive type in a substrate of a second conductive type; forming a body region of the first conductive type in the deep well; forming a well of the first conductive type in the deep well; forming an impurity layer of the first conductive type and a well of the first conductive type in the substrate at one side of the body region; forming a gate electrode over the substrate corresponding to a region in which the impurity layer is formed; and then forming a source region in the body region and a drain region in the well.

### DRAWINGS

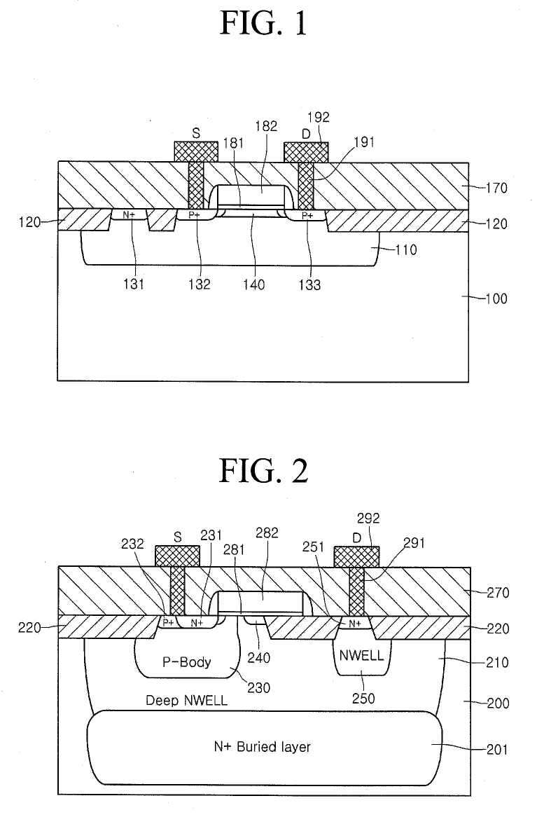

Example FIGS. 1 and 2 illustrate a logic PMOS device and an LDMOS device in accordance with embodiments.

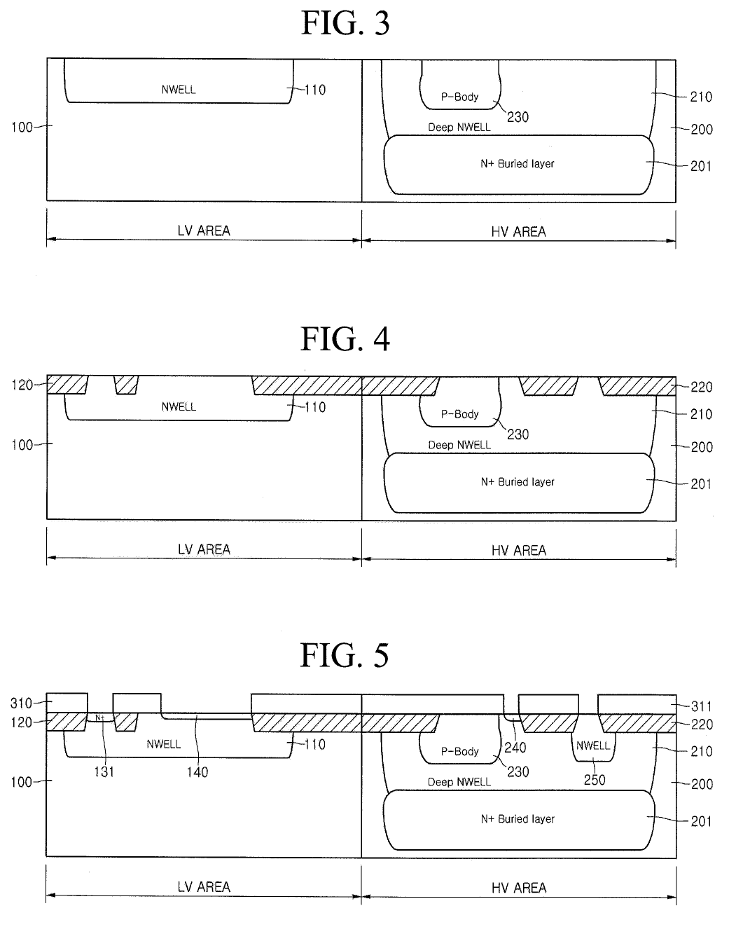

Example FIGS. 3 to 7 illustrate a method for manufacturing a semiconductor device in accordance with embodiments.

### DESCRIPTION

In the description of embodiments, it will be understood that when a layer (or film) is referred to as being “on” another layer or substrate, it can be directly on another layer or substrate, or intervening layers may also be present. Further, it will be understood that when a layer is referred to as being “under” another layer, it can be directly under another layer, and one or more intervening layers may also be present. In addition, it will also be understood that when a layer is referred to as being “between” two layers, it can be the only layer between the two layers, or one or more intervening layers may also be present.

Example FIG. 1 illustrates a PMOS device as a logic device operated at a low voltage (LV). As illustrated in example FIG. 1, first conductive type (N type) well 110 is formed in semiconductor substrate 100. Gate oxide layer 181 and gate electrode 182 are formed on and/or over an upper portion of semiconductor substrate 100. Second conductive type (P+ type) source region 132 is formed in substrate 100 at one side of gate electrode 182 and N+ type junction region 131 is formed as a high concentration junction region at one side of P+ type source region 132. Device isolation layers 120 therebetween is formed in substrate 100, one of which is interposed between N+ type junction region 131 and P+ type source region 132.

P+ type drain region 133 having a second conductive type structure, is formed in substrate 100 at the other side of gate electrode 182 opposite to P+ type source region 132. In accordance with embodiments, a region forming a channel between source region 132 and drain region 133 is formed in substrate 100 as a first conductive type impurity layer. Meaning, first conductive type impurity layer 140 is formed in substrate 100 underneath gate electrode 182 in order to effectively permit a flow of current. First conductive type impurity layer 140 may be formed using a mask used for a logic CMOS device or a PMOS device, etc., such that it can be formed without performing a process such as additional PR patterning, etc.

In the LDMOS device to be described below, the first conductive type impurity layer performs a role of reducing the on resistance.

Spacers formed on side walls of gate electrode 182 and gate oxide layer 181 are formed by any known methods. Interlayer dielectric layer 170 is formed on and/or over the entire semiconductor substrate 100 including gate electrode 182. Metal layer patterns 192 are connected to source region 132 and drain region 133, respectively, by way of contact plugs 191 which penetrate through interlayer dielectric layer 170.

As illustrated in example FIG. 2, a LDMOS device in accordance with embodiment has a first conductive type high-concentration N type buried layer 201 that is deeply formed in P type semiconductor substrate 200 that is a second conductive type. Device isolation layers 220 are formed in substrate 200.

N type buried layer 201 serves to reduce a width of a depletion region that is expanded from P type body 230 when a voltage is applied to N+ type drain region 251, such that it performs a role of substantially increasing a punch through voltage.

A P type epitaxial layer may also be formed in buried layer 201 by growing its crystal along a crystal axis of P type substrate 200 when a semiconductor crystal in a gaseous state is precipitated on a single crystalline wafer performing a role of a substrate, such that it performs a role of reducing the resistivity of P type substrate 200.

N type deep well 210 is formed in semiconductor substrate 200 and a channel region is formed near a surface of P type body 230 that exists between a contacting surface at which P type body 230 contacts N type deep well 210 and N+ type source region 231 in accordance with a bias voltage applied to gate electrode 282.

Gate oxide layer 281 and gate electrode 282 are formed on and/or over a predetermined portion of substrate 200. Spacers may be formed on and/or over both side walls of gate electrode 282 and gate oxide layer 281 by any known methods.

N type source region 231 and P+ type contact region 232 are formed in P-type body 230 at one side of gate electrode 282. P type body 230 may be formed in N type deep well 251 at relatively high-concentration in order to enhance the punch through phenomenon of the LDMOS. N+ type drain region 251 is formed in N-type well 250 at the other side of gate electrode 282. N-type well 250 is formed in N type deep well 210.

In accordance with embodiments, N type impurity layer 240 is formed in substrate 200 underneath gate electrode 282 between P type body 230 and device isolation layer 220 in order to reduce the on resistance of the LDMOS device. N type impurity layer 240 is formed at a predetermined distance from P type body 230. Since N type impurity layer 240 is doped with the same first conductive type (N type) impurities as drain region 251, the movement of electrons or holes through the channel formed within P type body 230 is further promoted by N type impurity layer 240. Accordingly, the on resistance characteristic of the LDMOS device can be lowered.

Moreover, interlayer isolation layer 270 is formed on and/or over semiconductor substrate 200 including gate electrode 282. Contact plugs 291 are formed penetrating through interlayer isolation layer 270 and are connected to N+ type source region 231 and N+ type drain region 251, respectively. Metal plugs 292, which are connected to contact plugs 291, are formed on and/or over interlayer isolation layer 270.

In the LDMOS device in accordance with embodiments, the flow of current is further promoted by N type impurity layer 240 that is formed at a predetermined distance or interval from P type body 230 such that the on resistance of the device can be lowered.

Example FIGS. 3 to 7 illustrate a semiconductor substrate that has the logic PMOS device, which is a low voltage region, and the LDMOS device, which is a high voltage region, with respect to the semiconductor substrate. In order to divide a process for manufacturing each device, it should be noted that other reference numerals refers to the semiconductor substrate.

As illustrated in example FIG. 3, the logic device and the LDMOS device are defined in the semiconductor substrate and substrate 100 of the logic device is formed with N type well 110 and substrate 200 of the LDMOS device is formed with N+ type buried layer 201 having a first conductive type. An epitaxial layer may be formed on and/or over substrate 200 of the LDMOS device, making it possible to form a P type epitaxial layer. N type deep well 210 is formed on and/or over buried layer 201 of substrate 200. P type body 230 having a second conductive type is formed in N type deep well 210.

As illustrated in example FIG. 4, a plurality of device isolation layers 120, 220 are formed spaced apart in first substrate 100 and second substrate 200 of the logic device and the LDMOS device.

As illustrated in example FIG. 5, an ion injection process is performed on the logic device in order to form N+ type junction region 131 and impurity layer 140 having the first conductive type in N type well 110. The ion injection process is also performed on the LDMOS device in order to form first conductive impurity layer 240 and N type well 250 on the lower side of the drain region. In particular, a plurality of photoresist patterns 310, 311 are formed on and/or over substrates 100, 200 as an ion injection mask for forming N+ type junction region 131 and N type well 250 to expose a region in which first conductive impurity layer 140 of the logic device will be formed and a region in which first conductive type impurity layer 240 in the LDMOS device will be formed. In accordance with embodiments, the process of forming N+ type junction region 131, first conductive impurity layers 140, 240 may be formed simultaneously.

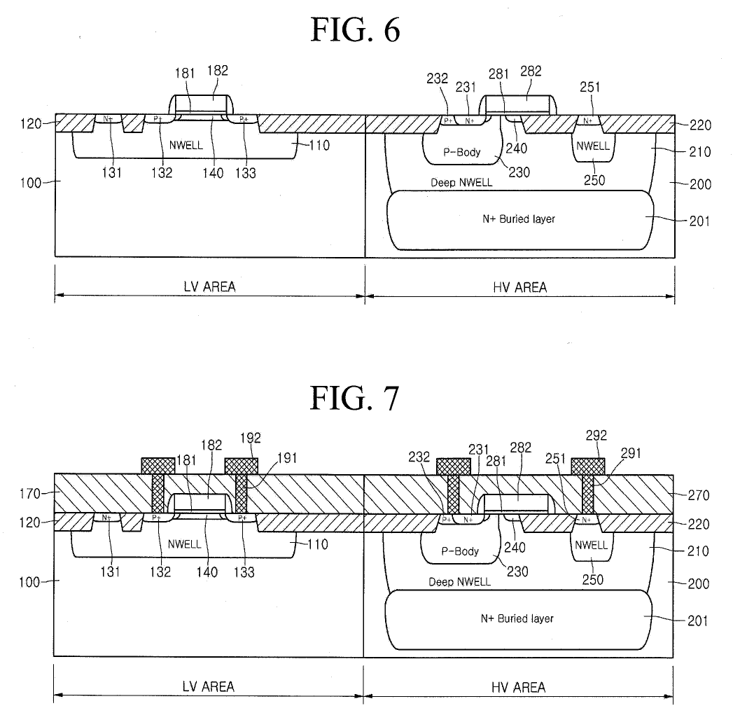

As illustrated in example FIG. 6, after conducting the process of forming first conductive impurity layers 140, 240 is performed, the photoresist patterns 310, 311 are removed. Then, gate oxide layers 181, 281 and corresponding gate electrodes 182, 282 are formed on and/or over each respective substrate 100, 200. An ion injection process is performed on the logic device to form source region 132 and drain region 133 in substrate 100 and also on the LDMOS device to form N+ type source region 251, P+ type contact region 232 and N+ type drain region 251 in substrate 200.

As illustrated in example FIG. 7, interlayer isolation layers 170, 270 are formed on and/or over substrates 100, 200 of the logic device and the LDMOS device. Contact plugs 191, 291, which penetrate through interlayer isolation layers 170, 270 and directly contacts the source and drain regions, are formed therein. Metal electrodes 192, 292, which are electrically connected to respective contact plugs 191, 291, are formed on and/or over interlayer isolation layers 170, 270.

In accordance with embodiments, with the semiconductor device and the method for manufacturing the same as described above, the impurity layer is formed in the substrate underneath the gate electrode to reduce the on resistance of the LDMOS device.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a substrate;
a first well having a first conductive type formed in the substrate; and
an LDMOS device including a gate electrode formed on the substrate, a source region formed in the substrate at one side of the gate electrode, a drain region formed in the substrate at another side of the gate electrode, and an impurity layer having the first conductive type formed in the substrate under the gate electrode.

2. The semiconductor device of claim 1, further comprising a device isolation layer formed in the substrate under a portion of the gate electrode.

3. The semiconductor device of claim 2, wherein the impurity layer having the first conductive type is formed between the source region and the device isolation layer.

4. The semiconductor device of claim 1, further comprising:
a body region having a second conductive type formed in the substrate under a portion of the gate electrode.

5. The semiconductor device of claim 4, wherein the source region is formed in the body region having the second conductive type.

6. The semiconductor device of claim 5, wherein the impurity layer is formed between the body region having the second conductive type and the drain region.

7. The semiconductor device of claim 1, further comprising a logic device including a second gate electrode formed on the substrate, a second source region, a second drain region and a second impurity layer having a first conductive type formed in the substrate under the gate electrode.

8. The semiconductor device of claim 7, wherein the second impurity layer having the first conductive type is formed between the second source region and the second drain region.

9. The semiconductor device of claim 7, wherein the impurity layer having the first conductive type of the LDMOS device and the second impurity layer having the first conductive type of the logic device are injected with an N type impurity.

10. A semiconductor device comprising:
a first substrate;
a second substrate;
a logic device including a first well of a first conductive type formed in the substrate, a first source region and a first drain region formed in the first well, and a first gate electrode formed over the first well; and
a LDMOS device including a deep well of the first conductive type formed in a second substrate, a body region of a second conductive type and a second well of a first conductive type formed in the deep well, a second source region formed in the body region, a second drain region formed in the second well, a second gate electrode formed over the second substrate, and an impurity layer of the first conductive type formed in the second substrate under the second gate electrode.

11. The semiconductor device of claim 10, wherein the second gate electrode partially overlaps the second source region.

12. The semiconductor device of claim 11, wherein the second gate electrode partially overlaps the body region.

13. The semiconductor device of claim 10, further comprising a second impurity layer of the first conductive type formed in the first substrate under the first gate electrode.

14. The semiconductor device of claim 10, wherein the impurity layer of the LDMOS device is formed between the body region and the second drain region.

15. The semiconductor device of claim 10, further comprising:
an interlayer dielectric layer formed over the first and second substrates;
a plurality of contact plugs formed extending through the interlayer dielectric layer and contacting the first source region, the second source region, the first drain region and the second drain region;
a plurality of electrodes formed over the interlayer dielectric layer and electrically connected to a respective one of the first source region, the second source region, the first drain region and the second drain region by a respective one of the contact plugs.

16. The semiconductor device of claim 10, further comprising:
a device isolation layer formed in the second substrate and under a portion of the second gate electrode.

17. The semiconductor device of claim 16, wherein the impurity layer is formed between the body region and the device isolation layer.

18. A method for manufacturing a semiconductor device comprising:
forming a deep well of a first conductive type in a substrate of a second conductive type;
forming a body region of the first conductive type in the deep well;
forming a well of the first conductive type in the deep well;
forming an impurity layer of the first conductive type and a well of the first conductive type in the substrate at one side of the body region;
forming a gate electrode over the substrate corresponding to a region in which the impurity layer is formed; and then
forming a source region in the body region and a drain region in the well.

19. The method of claim 18, wherein forming the impurity layer comprises injecting the first conductive type impurity into a region between the body region and the well.

20. The method of claim 18, wherein forming the impurity layer comprises:
forming a photo resist pattern exposing a region in which the impurity layer is formed and a region in which the well is formed; and then
injecting an N type impurity using the photo resist pattern as an ion injection mask into the region in which the impurity layer is formed.
